(19) United States
(12) Patent Application Publication
(10) Pub. No.: US 2026/0126733 A1
(43) Pub. Date: May 7, 2026

(54) SYSTEM AND METHOD FOR SUPPRESSION OF BACKGROUND SIGNAL IN TIME RESOLVED METROLOGY SIGNALS

(71) Applicant: Onto Innovation Inc., Wilmington, MA (US)

(72) Inventors: Robin A. Mair, West Chicago, IL (US); Matthew Sartin, Budd Lake, NJ (US); Manjusha Mehendale, Morristown, NJ (US); George Andrew Antonelli, Flanders, NJ (US); Julien Michelon, Merignac (FR); Xavier Tridon, Bordeaux (FR); Marco A;ves, Newark, NJ (US); Michael J. Kotelyanskii, Chatham, NJ (US)

(73) Assignee: Onto Innovation Inc., Wilmington, MA (US)

(21) Appl. No.: 19/425,566

(22) Filed: Dec. 18, 2025

Related U.S. Application Data
(63) Continuation-in-part of application No. 18/986,584, filed on Dec. 18, 2024.
(60) Provisional application No. 63/636,334, filed on Apr. 19, 2024.

(51) Int. Cl. G03F 7/00

(52) U.S. Cl. CPC G03F 7/706849; G03F 7/70625; G03F 7/706847; G03F 7/706851

(57) ABSTRACT

A time resolved reflectance metrology device may detect and image structures in a layer that underlies an at least partially transparent top layer. A pulsed laser beam (pump beam) is used to irradiate the sample to produce transient signals in the underlying layer. The transient signals are detected using a probe beam that reflects from the interface between the top layer and the underlying layer. Light from the probe beam that is reflected from the top surface of the top layer may be eliminated using a confocal lens arrangement before the detector. The confocal lens arrangement, for example, includes a pinhole that is positioned at the image plane for the interface between the top layer and the underlying layer. The structures may be detected and imaged based on the transient signals.

### CLAIM OF PRIORITY

This application claims the benefit of and priority to U.S. application Ser. No. 18/986,584, filed Dec. 18, 2024, and entitled “METROLOGY BASED ON TIME RESOLVED NON-ACOUSTIC SIGNALS,” which claims priority to U.S. Provisional Application No. 63/636,334, filed Apr. 19, 2024, and entitled “METROLOGY BASED ON TIME RESOLVED NON-ACOUSTIC SIGNALS,” both of which are assigned to the assignee hereof and are incorporated herein by reference in their entireties.

### FIELD OF THE DISCLOSURE

The subject matter described herein is related generally to microscopy, and more particularly to the use of time resolved reflectivity measurements.

### BACKGROUND

Semiconductor processing for forming integrated circuits requires a series of processing steps. These processing steps include, for example, the deposition and patterning of material layers such as insulating layers, polysilicon layers, and metal layers. For proper operation of such devices, the successful formation, patterning, and alignment of successive layers is sometimes crucial. The packaging of devices, particularly in advanced packaging processes in which multiple devices, including electrical, mechanical, or semiconductor, are aggregated and interconnected, similarly sometimes requires precise processing. For example, in one example of advanced packaging processes, two or more wafers or substrates may be bonded, e.g., attached together using a number of physical and chemical processes. During wafer bonding there is the potential of the presence of voids to be formed between bonded layers. The presence of voids may affect the overall yield.

There are various conventional optical techniques that may be used for non-destructive metrology or inspection of devices during processing, e.g., during fabrication or packaging.

For example, conventional techniques may use specific wavelengths of light, e.g., ultraviolet (UV), visible, or infrared (IR), to image or otherwise detect one or more structures produced during processing. However, conventional optical techniques are sometimes unsuitable for the measurement or detection of such structures when the structures are under optically opaque layers or are optically transparent to the specific wavelengths of light being employed. Accordingly, improved microscopy techniques are desirable.

### SUMMARY

Opto-acoustic metrology, in general, uses a pump beam and a probe beam with a varying time delay between light pulses in each of the pump and probe beams to detect structures that produce an acoustic response to the pump beam. The light pulses in the pump beam, for example, may produce an acoustic response from structures within the sample and the acoustic response propagates to the surface of the sample, which is detected by the probe beam. The acoustic response, for example, affects the reflectivity of the material in the sample or deflection of the probe beam. Some buried structures, however, do not produce an acoustic response and, accordingly, are not detectable using conventional opto-acoustic metrology. As discussed herein, however, a time resolved reflectance metrology device may detect and image buried structures that do not produce acoustic signals based on time resolved transient signals acquired from non-acoustic transient perturbations produced in response to a pump beam.

Buried structures, such as voids or inclusions, that do not produce acoustic signals in response to pump beams are detected and imaged using the time resolved reflectance metrology device, based on the processing of the time resolved transient signals at a plurality of locations. The buried structures, for example, may be present in non-metallic, optically transparent layers that do not produce acoustic signals in response to pump beams. Non-acoustic transient perturbations are produced in response to a pump beam at a plurality of locations due to physical phenomena such as one or more of thermal dissipation, electron-hole recombination, plasma diffusion, symmetry breaking at top and bottom oxide surfaces, etalon effects. Non-acoustic transient signals are detected using a probe beam at the plurality of locations. The pump beam and probe beam have a varying delay to produce time resolved measurements of the transient signals. The buried structures are detected and imaged using a feature analysis (e.g., principal component decomposition, or polynomial fit, or other) for the non-acoustic transient signals at the plurality of locations.

The sample may include a thick top layer and the structures may be present in an underlying layer. The wavelengths of light used in the pump and probe beams may be selected such that the top layer is at least partially transparent to the light, while the underlying layer is opaque. Light reflected from the top surface of the top layer may be rejected using a confocal lens arrangement before the detector.

In one implementation, a metrology device is configured for non-destructive detection of structures in a sample. The metrology device includes a pump arm that irradiates the sample with pump pulses to cause transient perturbations in material in a layer with the structures that underlies a top layer in the sample. A probe arm irradiates the layer that underlies the top layer of the sample with probe pulses to produce a reflected probe beam that is modulated based on a response of the material to the transient perturbations in the sample, wherein the probe pulses penetrate the top layer that is at least partially transparent to wavelengths of light used by the probe arm. The metrology device includes a detector that acquires transient signals from the reflected probe beam in response to the transient perturbations that are a function of varying time delay between the pump pulses and the probe pulses. The metrology device further includes at least one processor coupled to the detector and that is configured to detect at least one structure in the layer that underlies the top layer in the sample based on the transient signals.

In one implementation, a method for non-destructive detection of structures in a sample includes irradiating the sample with a pump beam with pump pulses to cause transient perturbations in material in a layer with the structures that underlies a top layer in the sample. The layer that underlies the top layer of the sample is irradiated with a probe beam with probe pulses to produce a reflected probe beam that is modulated based on a response of the material to the transient perturbations in the sample, wherein the probe pulses penetrate the top layer that is at least partially transparent to wavelengths of light used in the probe pulses. The method includes detecting transient signals from the reflected probe beam in response to the transient perturbations that are a function of varying time delay between the pump pulses and the probe pulses. The method further includes detecting at least one structure in the layer that underlies the top layer in the sample based on one or more features of the transient signals.

In one implementation, a metrology device is configured for non-destructive detection of structures in a sample. The metrology device includes a pump arm that irradiates the sample with pump pulses to cause transient perturbations in material in a layer with the structures that underlies a top layer in the sample. A probe arm irradiates the layer that underlies the top layer of the sample with probe pulses to produce a reflected probe beam that is modulated based on a response of the material to the transient perturbations in the sample, wherein the probe pulses penetrate the top layer that is at least partially transparent to wavelengths of light used by the probe arm and the probe pulses reflect from a top surface of the top layer and from an interface between the layer and the top layer. The metrology device includes a detector that acquires transient signals from the reflected probe beam in response to the transient perturbations that are a function of varying time delay between the pump pulses and the probe pulses. The metrology device further includes a means for preventing reflections from the top surface of the top layer from being detected by the detector and at least one processor coupled to the detector and that is configured to detect at least one structure in the layer that underlies the top layer in the sample based on the transient signals.

### BRIEF DESCRIPTION OF THE DRAWINGS

FIG. 1 illustrates a block diagram of a time resolved reflectance metrology device that is configured to image buried structures in a sample based on the feature analysis of the time resolved transient signals at a plurality of locations.

FIG. 2 illustrates a block diagram of another time resolved reflectance metrology device that is configured to image buried structures in a sample based on the feature analysis of the time resolved transient signals at a plurality of locations.

FIG. 3A illustrates a schematic representation of acquiring transient signals from a plurality of locations on a sample in parallel using a lock-in camera.

FIG. 3B illustrates a schematic representation of acquiring transient signals from a plurality of locations on a sample sequentially in a scan of the sample using detector.

FIGS. 4A and 4B illustrate the detection of buried structures in a sample having one or more metallic layers using time resolved reflectance measurements produced by acoustic transient signals.

FIGS. 5A and 5B illustrate the detection of buried structures in a sample that does not produce acoustic signals using time resolved reflectance measurements produced by non-acoustic transient signals.

FIGS. 6A and 6B illustrate the imaging and detection of buried structures in a sample that does not produce acoustic signals using time resolved reflectance measurements produced by non-acoustic transient signals from a plurality of locations.

FIG. 7 is a flow chart illustrating a process of non-destructive detection of buried structures in a sample using non-acoustic transient signals.

FIG. 8 illustrates the detection of structures in a sample using time resolved reflectance measurements from an interface between a top layer and an underlying layer when there are reflections from the top surface of the top layer.

FIG. 9 illustrates an example portion of a time resolved reflectance metrology device that includes a confocal lens arrangement to reject reflections from the top surface of the top layer.

FIG. 10 illustrates a simplified view of the optical path including a sample, an objective lens, and a detector, without the use of a confocal lens arrangement.

FIG. 11 illustrates a simplified view of the optical path including a sample, an objective lens, a confocal lens arrangement, and a detector.

FIG. 12 is a flow chart illustrating a process of non-destructive detection of structures in a sample using transient signals.

### DETAILED DESCRIPTION

Non-destructive metrology techniques may be used to ensure proper processing of semiconductor or other similar devices. For example, during processing, a series of fabrication steps may be performed in which layers, such as insulating layers, polysilicon layers, and metal layers, are deposited and patterned. In another example, during processing advanced packaging processes may be used to interconnect two or more devices during packaging. During processing, e.g., fabrication and packaging, desired or undesired buried structures may be produced in the sample, e.g., structures under one or more layers. A sample may be a wafer, a panel, or any type of substrate. The detection or measurement of such structures using non-destructive metrology techniques may be necessary or desirable to ensure proper processing for proper operation of resulting devices and to increase yield.

By way of example, during advanced packaging processes, two or more wafers or substrates may be bonded together using a number of physical and chemical process techniques. During the bonding process, structures such as voids or inclusions may be intentionally or inadvertently formed between bonded layers. It may be desirable to detect the presence or measure such structures during processing. For example, the structures may be useful to ensure proper alignment of the wafers. Similar to fabrication processing techniques, structures may be formed in a series of processing steps, such as the deposition and patterning of material layers such as insulating layers, polysilicon layers, and metal layers. For proper operation of such devices, the successful formation, patterning, and alignment of successive layers during fabrication and packaging is sometimes crucial. Moreover, inadvertently formed structures may affect the final performance of devices and accordingly, may adversely affect the overall yield. If undesired characteristics, such as improper alignment or undesired structures, are detected, it may be possible to rework bonded wafers before additional processing is performed, such as polishing, etc.

There are various conventional optical techniques that may be used for non-destructive metrology or inspection of devices during the processing, e.g., during fabrication or packaging. Non-destructive techniques for metrology or inspection of devices during processing, e.g., during fabrication or packaging, often rely on the use of light. For example, conventional techniques may use specific wavelengths of light, e.g., ultraviolet (UV), visible, or infrared (IR), to image or otherwise detect one or more structures produced during processing.

Typically, to conventionally detect or image buried structures, e.g., structures that are under one or more layers, light having wavelengths suitable to penetrate the overlying layers is used. However, conventional optical techniques are sometimes unsuitable for the measurement or detection of buried structures when the structures are under optically opaque layers or the structures are optically transparent to the specific wavelengths of light being employed. In some instances, for example, overlying layers, or the layer in which the structure is formed, may be formed with a material that is opaque to light, e.g., when the material is metal. In such instances, it may not be possible to conventionally image the buried structures. As another example, voids or inclusions may be buried in between layers that are underneath a full layer of silicon (Si), e.g., 750 μm. Such structures may be difficult to detect or image as the structure, e.g., voids or inclusion, is optically transparent to the light. In some instances, infrared imaging may be possible to image such structures, unless the structures are covered by opaque layers, e.g., metal layers. Unfortunately, the resolution of infrared imaging technology is limited, making such techniques generally unsuitable even for voids that are not covered by metal layers.

One type of non-destructive metrology technique that is used to detect voids is confocal scanning acoustic microscopy (C-SAM), which uses acoustic signals. Unfortunately, for proper conduction of the acoustic signal with C-SAM technology, the sample is submerged in water, which is generally undesirable for many samples, such as semiconductor or other similar devices. Moreover, C-SAM technology is not able to image relatively small voids, e.g., sizes below 10 μm, and therefore has limited use.

Another type of non-destructive metrology technique is opto-acoustic metrology, which uses a pump beam and a probe beam with a varying time delay between light pulses in each of the pump and probe beams to detect structures that produce an acoustic response to the pump beam. The light pulses in the pump beam, for example, may produce an acoustic response from structures within the sample and the acoustic response propagates to the surface of the sample, which is detected by the probe beam. The acoustic response, for example, affects the reflectivity of the material in the sample or deflection of the probe beam. Buried structures, such as voids or inclusions, however, do not produce an acoustic response and, accordingly, are not detectable using conventional opto-acoustic metrology.

As disclosed herein, time resolved transient signal measurements may be used to detect and image buried structures, such as voids or inclusions, even when the structure is underneath non-metal layers. As an example, the non-acoustic transient signal measurements to detect or image the buried structures may be performed using a time resolved reflectance metrology device, such as a picosecond laser acoustic (PLA) measurement device. A time resolved reflectance metrology device, such as PLA, for example, may use an ultrafast laser (˜100 fs pulse width) allowing resolution of a few femtoseconds. While PLA measurement devices are conventionally used to measure acoustic return signals, as discussed herein, little or no acoustic return signal may be produced by some structures being measured. The time resolved transient signals that are measured with such structures, as discussed herein, are non-acoustic. Non-acoustic transient signals, for example, may be produced by physical phenomena that, by way of example, may include one or more of thermal dissipation, electron-hole recombination, plasma diffusion, symmetry breaking at top and bottom oxide surfaces, and etalon effects.

While the measured return signal may include some acoustic information, the detection or imaging of the buried structures is based on the non-acoustic information in the transient signals, and accordingly, the measured return signal is referred to herein as a non-acoustic transient signal. The use of non-acoustic transient signal measurement enables the detection of structures, such as voids that are under non-metal layers, and that cannot be measured using conventional metrology techniques that rely on acoustic signals.

As discussed herein, a time resolved reflectance metrology device that measures non-acoustic transient signals uses pump beams and probe beams with a varying delay. A pump arm, for example, is configured to irradiate a sample at a plurality of locations with pump pulses that cause non-acoustic transient perturbations in the material in the sample at the plurality of locations. A probe arm is configured to irradiate the sample at the same locations with probe pulses, which produces a reflected probe beam. The reflected probe beam is at least partially modulated based on the non-acoustic transient perturbations in the material in the sample. In some implementations, one or more modulators may be used to modulate, e.g., frequency modulate intensity, the pump pulses, the probe pulses, or both pump pulses and the probe pulses, which may be used to extract the non-acoustic transient perturbations from the reflected probe beam. A detector acquires the transient signals from the reflected probe beam in response to the non-acoustic transient perturbations that are a function of varying time delay between the pump pulses and the probe pulses at each of the plurality of locations. At least one processor receives the detected transient signals and generates an image of the sample, including buried structures, such as voids or inclusions, based on feature analysis (e.g., principal component decomposition, or polynomial fit, or other) of the transient signals at each of the plurality of locations. The time resolved reflectance metrology device may be configured to produce the variable time delay between the pump pulses and the probe pulses using a translating delay line in the pump or probe arm, or using an asynchronous optical sampling (ASOPS) configuration in which two synchronized lasers with slightly different repetition rates produce the variable time delay without a mechanical delay line. The pump beam and probe beam may irradiate the plurality of locations sequentially, e.g., in a raster scan of the sample. In another implementation, the plurality of locations may be irradiated simultaneously, and the detector may use a multi-pixel array to acquire the transient signals in parallel.

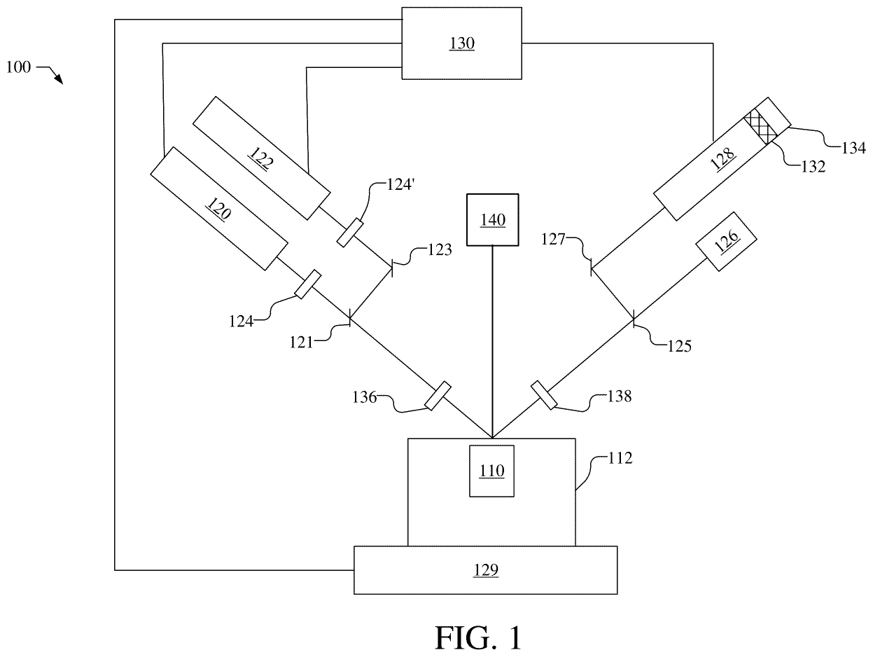

FIG. 1 illustrates a block diagram of an example time resolved reflectance metrology device 100 that is configured to image buried structures in a sample based on the feature analysis (e.g., principal component decomposition, or polynomial fit, or other) of the time resolved transient signals at a plurality of locations, as discussed herein.

The device 100 includes a pump laser 120 (also referred to herein as an excitation laser), a probe laser 122 (also referred to herein as a detection laser), and optical elements, such as turning mirror 123 and beam splitter 121, as well as lenses 136 and 138, filters, polarizers and the like (not shown) that direct light from the pump and probe lasers 120, 122 to the sample 112 that includes a buried structure 110 to be imaged. The device may further include a modulator 124, e.g., such as an electro-optic modulator (EOM), that modulate the pump pulses in the pump arm with a modulation frequency, and in some implementations, a second modulator 124′ that modulates the probe pulses in the probe arm with a different modulation frequency. The device 100 may include optical elements such as beam splitter 125 and turning mirror 127 and may include a beam dump 126 for capturing radiation from the pump laser returned from the sample 112. The device 100 includes a detector 128 that detects a change in reflectivity or surface deformation of the sample 112 at every measurement location as a function of a time delay between the pump pulses and the probe pulses. It should be understood that for ease of reference, the reflectivity or deflection from the sample collectively may sometimes be referred to herein generally as reflectance.

In some implementations, the detector 128 may be coupled to a demodulator, such as a lock-in amplifier that is configured for phase locking during acquisition of signals. In some implementations, the detector 128 may be a lock-in camera that includes a multi-pixel array 132 and independent phase locking for each pixel in the multi-pixel array and is configured to detect, in parallel, the changes in reflectivity or surface deformation of the sample 112 at every pixel as a function of a time delay between the pump pulses and the probe pulses. With the use of a multi-pixel array 132 with independent phase locking for each pixel, the light from the pump and probe lasers 120, 122 is focused in a relatively large spot and each pixel corresponds to a different location on the sample 112.

In some implementations, the detector 128 may be a photodiode or other type of single pixel detector and is configured to detect the changes in reflectivity or surface deformation of the sample 112 at a single location as a function of a time delay between the pump pulses and the probe pulses. The device 100 further includes a mechatronic support 129 for a sample 112 of which structure 110 is a part, the mechatronic support 129 being adapted to move the sample 112 relative to the pump and probe lasers 120, 122 to obtain measurements at multiple locations sequentially, e.g., in a raster scan.

The device further includes a processing system 130 coupled to the pump and probe lasers 120, 122, the mechatronic support 129, and the detector 128. It should be appreciated that the processing system 130 may be a self-contained or distributed computing device capable of performing computations, receiving, and sending instructions or commands and of receiving, storing, and sending information related to the metrology functions of the device.

In the depicted implementation, the pump and probe lasers 120, 122 in the implementation of the time resolved reflectance metrology device 100 shown in FIG. 1 can share at least a portion of an optical path to and from the structure 110. For example, the lasers can have a number of different relative arrangements including a configuration wherein the paths are the same, partially overlapping, adjacent, or coaxial. In some implementations, the pump and probe beams may be derived from the same pulsed laser. In some implementations, as illustrated in FIG. 1, separate lasers may be used for the pump and probe beams, e.g., separate synchronized lasers with slightly different repetition rates may be used in an asynchronous optical sampling (ASOPS) configuration. In other implementations, the pump and probe lasers 120, 122 and the beam dump 126 and detector 128 do not share optical paths. For example, the pump beam from the pump laser 120 may be normally incident on the sample 112, while the probe beam from the probe laser 122 may be obliquely incident on the sample 112. The pump and probe lasers 120, 122 may be controlled directly so as to obtain the temporal spacing between the pulses of light directed to the structure 110.

It should be appreciated that many optical configurations are possible. In some configurations the pump can be a pulsed laser with a pulse width in the range of several hundred femtoseconds to several hundred nanoseconds and the probe beam is coupled to a beam deflection system. For example, in systems wherein the probe is also pulsed the device can employ a delay stage (not shown) for increasing or decreasing the length of the optical path between the laser and the sample 112 associated therewith. The delay stage, where provided, would be controlled by processing system 130 to obtain and control the time delays between the pump and probe light pulses that are incident on the object. Many other alternative configurations are also possible. In other implementations, such as with an ASOPS configuration, the device may not include a delay stage. It should be appreciated that the schematic illustration of FIG. 1 is not intended to be limiting, but rather depict one of a number of example configurations.

In operation, the time resolved reflectance metrology device 100 directs a series of pulses of light from pump laser 120 to the structure 110. These pulses of light are incident on the sample 112, e.g., at an angle which can be any angle between zero to 90 degrees including, for example, 45 degrees and 90 degrees). If the sample 112 includes an at least partially absorbing transducer layer, e.g., a metallic layer, above the structure 110, the pulses of light from the pump laser 120 are at least partially absorbed causing a transient expansion, i.e., acoustic signal, in the material of the transducer layer. The expansion is short enough that it induces what is essentially an ultrasonic wave that propagates vertically through the structure 110 and is reflected at each underlying interface and is returned to the top surface. Light from the pump laser 120 that is reflected from the structure 110 is passed into a beam dump 126 which extinguishes or absorbs the pump radiation.

On the other hand, if the sample 112 does not include a strongly absorbing material such as a metallic layer, and only includes materials that are optically transparent to the wavelengths used by the pump laser 120, there may be no (or only a minor) transient expansion, i.e., acoustic signal, that is produced. Nevertheless, a non-acoustic transient signal in the sample 112 is produced in response to the pump pulses from one or more different physical phenomena, such as thermal dissipation, electron-hole recombination (e.g., possible generated in Si), plasma diffusion, symmetry breaking at top and bottom oxide surfaces, etalon effects within a void, etc. Without a strongly absorbing material to produce an acoustic signal, the non-acoustic contributions to the return signal become more prominent and sensitive to the presence of structures, such as voids in oxide layers.

In addition to directing the operation of the pump laser 120, the processing system 130 directs the operation of the probe laser 122. Probe laser 122 directs radiation in a series of light pulses that is incident on the sample 112, which reflect from the top layer of the sample 112 and is affected by the return signals, e.g., reflected acoustic signals if the sample 112 includes a strongly absorbing material to produce acoustic signals, or the non-acoustic transient signals if strongly absorbing materials are not present in the sample 112.

FIG. 1 illustrates a modulator 124 that modulates the pump pulses from the pump laser 120. Additionally, modulator 124′ may be used to additionally modulate the probe pulses from the probe laser 122. The modulators 124 and 124′, for example, may be EOMs, and may intensity modulate the pump pulses or both the pump pulses and the probe pulses, e.g., with two frequency combs.

The device 100 includes optical elements, such as lens 136, that may be configured to adjust the spot sizes of the pump beam and probe beam. The spot sizes of the respective beams may be similar or dissimilar. For example, the optical elements, such as lens 136, may be configured to adjust a focal area of the pump pulses and the probe pulses on the sample 112 to a size that includes a plurality of locations to be measured, e.g., using a lock-in camera that includes a multi-pixel array 132 as the detector 128, or to a size that corresponds to a single location, if the detector 128 is a single pixel detector and scanning is used to measure the plurality of locations.

The light reflected from the surface of the sample 112 is directed to the detector 128, e.g., by beam splitter 125. The reflectance of the reflected probe beam is altered due to changes in reflectivity or surface deformation due to the reflected acoustic waves returning to the top surface, if present, or due to the non-acoustic transient signals at the top surface. The detector 128 may be configured to receive and demodulate the reflected probe pulses, e.g., using one or more lock-in amplifiers in a phase-locking circuit 134.

In implementations in which the detector 128 includes a multi-pixel array 132, the optical elements, such as lens 138, may adjust the magnification of the probe beam on the multi-pixel array 132 for efficiency. The detector 128 may include the phase-locking circuit 134 that is configured for phase locking to acquire the transient signals. If the detector 128 includes the multi-pixel array 132, the phase-locking circuit 134 is configured for independent phase locking for each pixel in the multi-pixel array for parallel acquisition of transient signals. In some implementations, the phase-locking circuit 134 may be independent of the detector 128, e.g., in a separate processor or Field Programmable Gate Array (FPGA). The phase locking may be used to demodulate the frequency of the pump pulses in the received probe beam. If both the pump pulses and probe pulses are modulated by modulators 124 and 124′, respectively, a combination, e.g., a sum or difference, of the frequencies in the received probe beam may be demodulated. The detector 128 may record a change in reflectivity or surface deformation of the sample 112, e.g., for each illuminated pixel, as a function of a time delay between the pump pulses and the probe pulses. For example, the detector 128 may generate a plurality of images of the sample 112 with each image produced with a different time delay between the pump pulse and the probe pulse.

The pump pulses and probe pulses may be produced with different delays, and the detector 128 may generate images of a plurality of locations on the sample with each image produced with a different time delay between the pump pulses and probe pulses. If the changes in reflectance are due to reflected acoustic waves returning to the top surface of the sample 112, each image generated by the detector 128, may correspond to an arrival of the acoustic transient signals from underlying layers and structures at different depths within the sample 112, and the depth of the structures may be determined based on the time delay. On the other hand, if there are no or little acoustic signals returned to the surface, the changes in reflectance are due to non-acoustic transient signals at the top surface of the sample 112, and the attributes or traits of the transient signals, such as rate of decay or other characteristics of the non-acoustic transient signals may be determined based on the time delay between the pump pulses and probe pulses.

In addition, the time resolved reflectance metrology device 100 may be coupled with an imaging device 140 that is configured to image the top surface of the sample 112, e.g., for alignment or overlay purposes. The imaging device 140, for example, may be the navigation channel camera. The imaging device 140 may perform optical imaging of the sample 112.

The processing system 130 includes at least one processor that is configured to collect and analyze the data obtained from the detector 128. The processing system 130 may analyze the time resolved reflectance metrology data to detect and image a buried structure 110, such as voids, in the sample 112. In some implementations, the underlying structure 110 may be detected and imaged based on analysis of the transient signal to differentiate between various attributes or traits of the transient signals from different locations. The attributes or trains of the transient signals from different locations may be used to determine whether the measurements are carried out at locations with voids or locations without voids. As an example, the analysis may be based on feature analysis (e.g., principal component decomposition, or polynomial fit, or other) of the transient signals detected at each of a plurality of locations on the sample 112. The transient signals, for example, may be produced in locations in which there are no strongly absorbing materials that produce acoustic signals so that non-acoustic transient signals are produced, i.e., signals in which any acoustic contribution is less than the contributions produced by other physical phenomena such as one or more of thermal dissipation, electron-hole recombination, plasma diffusion, symmetry breaking at top and bottom oxide surfaces, etalon effects, etc. The feature analysis (e.g., principal component decomposition, or polynomial fit, or other) of the transient signals, by way of example, may be a first degree (line) or a higher degree polynomial. The buried structures, such as voids, may be detected based on a comparison of the coefficients of the polynomial fits of the transient signals from a plurality of different locations. For example, in some implementations, the comparison may be based on or may include a slope or rate of change in the polynomial fits of the non-acoustic transient signals, from a plurality of different locations, which may be used to detect buried structures, such as voids. Using the raw time resolved reflectance metrology data, or processed data, such as its Fourier transform or differential reflectance, or a combination thereof, in an image of the structure, the position of the underling structure may be derived. In some implementations, a principal component analysis (PCA) process may be used on the data from the one or more images of the structure. Additionally, or alternatively, a non-PCA analysis may be used to identify a localized region in frequency space that captures the signal difference between regions on and off the underlying structure and to seek a highly correlating localized region in temporal space. The processing system 130 may alternatively or additional process the images obtained from the time resolved reflectance metrology data for edge detection or triangulation, e.g., using a classification library or neural network generated by the time resolved reflectance metrology device 200 (or another device) on a reference sample.

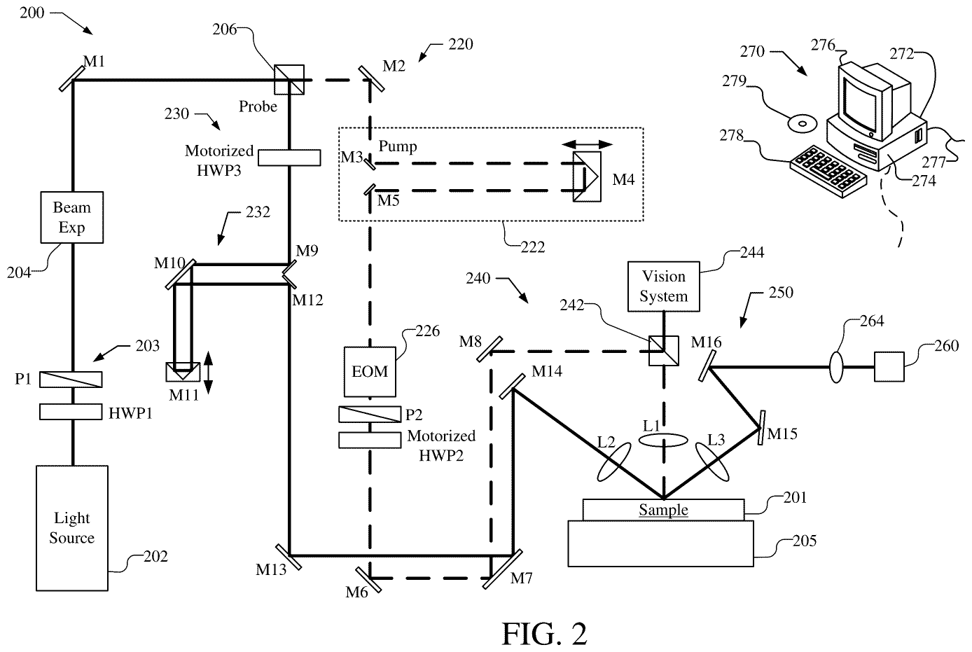

FIG. 2 illustrates a schematic representation of an example time resolved reflectance metrology device 200 that is configured to image buried structures in a sample based on the feature analysis (e.g., principal component decomposition, or polynomial fit, or other) of the time resolved transient signals at a plurality of locations, as discussed herein, as discussed herein. As illustrated, light may be produced from a light source 202, such as a 520 nm, 200 fs, 60 MHz laser. Other light source characteristics, however, may be used, including light sources that operate in the infrared wavelength ranges, e.g., for imaging buried structures. The light is directed through an intensity control 203, which may include a half wave plate HWP1 and a polarizer P1, and may be directed through a beam expander 204. The beam may be directed by mirror M1 to pump probe separator 206, which may include a polarizing beam splitter.

In the pump arm 220, the pump beam is directed by mirror M2 to a variable delay 222 that includes mirrors M3, M4, and M5, where mirror M4 moves to adjust the delay in the pump beam. The mirror M4, for example, may be a retroreflector or mirror coupled to an actuator or voice coil VC with a physical displacement of, e.g., approximately 25 mm or 83.3 ps for achieving a short repeatable pump pulse time delay. The pump beam passes through a modulator 226, e.g., an electro-optic modulator (EOM), followed by a polarizer P2 and a half wave plate HWP2, which may be motorized to rotate. The pump beam is directed by beam steering mirrors, e.g., mirrors M6, M7, and M8, to a focusing unit 240. At least one of the mirrors M6, M7, and M8 may be attached to a piezoelectric motor to adjust the direction of the pump beam. As illustrated in FIG. 2, the focusing unit 240 may include a beam splitter 242 that directs the pump beam through lens L1 to be normally incident on the sample 201. The lens L1 focuses the pump beam over an area of the sample 201 that includes the structure to be imaged. In some implementations, the pump beam may be obliquely incident on the sample 201, e.g., along the same beam path as the probe beam.

In the probe arm 230, after the pump probe separator 206, the probe beam may pass through a half wave plate HWP2, which may be motorized to rotate. The probe beam may be directed to a probe delay 232 that includes mirrors M9, M10, M11, and M12. The mirror M11, for example, may be a retroreflector and may be a coupled to an actuator or voice coil to adjust the delay of the probe beam. The probe beam is directed by beam steering mirrors, e.g., mirrors M13, M7, M14, to the focusing unit 240. At least one of the mirrors M13, M7, and M14 may be attached to a piezoelectric motor to adjust the direction of the probe beam. As illustrated in FIG. 2, the focusing unit 240 may direct the probe beam through lens L2 to be obliquely incident on the sample 201. The lens L2 focuses the probe beam over an area of the sample 201 that includes the structure to be imaged and that is coincident with the area of incidence of the pump beam. In some implementations, similar to the pump beam, the probe beam may pass through a modulator, e.g., an EOM, followed by a polarizer and a half wave plate, which may be motorized to rotate, to modulate the frequency of the probe beam, e.g., with a different frequency comb than the pump beam.

The lenses L1 and L2, for example, may be configured to generate coincident spots on the sample 201 that are at least a size of dimensions of a structure under test on the sample 201 so that scanning is not required to image the desired structure, such as an alignment or overlay pattern. In some implementations, for example, the lenses L1 and L2 may have a focal area greater than 20 μm.

The variable delay 222 and the probe delay 232 may be operated in an absolute or relative (with fixed amplitude and a sinusoidal waveform) displacement mode. For example, due to local topography and film thickness variation, localization in time delay may have poor capability preventing a faster scan. Data may be collected at a fixed position with a fixed amplitude (1.5 mm) sinusoidal oscillation at a frequency (10 KHz) of the retroreflector M14 on the voice coil yielding a delay of +/−5 ps. With the time constant optimized on the lock-in amplifiers for the sinusoidal oscillation, the voltage output may then be the average of the change in reflectance over the selected time delay range mitigating the noted concern of operating at a fixed position.

The reflected probe beam (and optionally reflected pump beam if obliquely incident) is received by collection optical elements 250 that includes, e.g., lens L3 and mirrors M15 and M16. The reflected beam is directed to a detector 260 via lens 264. Similar to detector 128 discussed in FIG. 1, the detector 260 may be a lock-in camera that includes a multi-pixel array or a photodiode or other type of single pixel detector. An image of the sample 201 may be generated using the multi-pixel array in the detector 260, if present, or by scanning the sample 201 (and/or optical elements) to a plurality of locations and performing measurements at each separate location.

The detector 260 is configured for phase locking during acquisition of transient signals. The phase locking may be used to demodulate the received probe beam based on the frequency of the pump pulses, or the combination of frequencies in both the pump pulses and probe pulses, produced by the modulator 226 (and modulator in the probe arm 230 if present). In implementations in which both the pump pulses in the pump beam and probe pulses in the probe beam are modulated with two different frequency combs (e.g., by modulators in both pump arm 220 and probe arm 230), the phase locking may be used to demodulate the combination, e.g., sum or difference, of the frequencies. Moreover, the phase locking may generate in-phase measurements and quadrature measurements from the images. The detector 260 may record a change in reflectivity or surface deformation of the sample 201 as a function of a time delay between the pump pulses and the probe pulses.

The pump pulses and probe pulses may be produced with different time delays and the detector 260 may detect the transient signals with different time delays.

In addition, the time resolved reflectance metrology device 200 may be coupled with an imaging device 244 that may be configured to image the top structure of the sample 201 via beam splitter 242 and lens L1. The imaging device 244, for example, may be the navigation channel camera.

The sample 201 is held on a stage 205 that includes or is coupled to one or more actuators configured to move the sample 201 relative to the optical system of the time resolved reflectance metrology device 200 so that various locations on the sample 201 may be measured. In the depicted implementation, the device may include additional components and subsystems, such as beam management and conditioning components, such as beam expanders, collimators, polarizers, half-wave plates, etc., as well as a beam power detector, and a height detector.

Those having skill in the art will appreciate variations of the devices depicted in FIGS. 1 and 2 that would still be suitable to carry out the time resolved reflectance metrology techniques described herein.

The detector 260, as well as other components of the time resolved reflectance metrology device 200, light source 202, variable delay 222, stage 205 upon which the sample 201 is held, may be coupled to a processing system 270, such as a workstation, a personal computer, central processing unit or other adequate computer system, or multiple systems. It should be understood that one processor, multiple separate processors or multiple linked processors may be used, all of which may interchangeably be referred to herein as processing system 270. The processing system 270 is preferably included in, or is connected to, or otherwise associated with time resolved reflectance metrology device 200. The processing system 270, for example, may control the positioning of the sample 201, e.g., by controlling movement of the stage 205 on which the sample 201 is held. The stage 205, for example, may be capable of horizontal motion in either Cartesian (i.e., X and Y) coordinates, or Polar (i.e., R and θ) coordinates or some combination of the two. The stage 205 may also be capable of vertical motion along the Z coordinate. The processing system 270 may further control the operation of a chuck on the stage 205 used to hold or release the sample 201.

The processing system 270, similar to processing system 130 discussed in FIG. 1, may collect and analyze the data obtained from the detector 260. The processing system 270 may analyze the time resolved reflectance metrology data to detect and image a buried structure, such as voids, in the sample 201. For example, in some implementations, an underlying structure may be detected and imaged based on analysis of the transient signal to differentiate between various attributes or traits of the transient signals from different locations. The attributes or traits of the transient signals from different locations may be used to determine whether the measurements are carried out at locations with voids or locations without voids. As an example, the analysis may be based on polynomial fits of the transient signals detected at each of a plurality of locations. The transient signals, for example, may be non-acoustic transient signals, i.e., signals in which contributions from any acoustic signal is less than the contributions produced by other physical phenomena such as one or more of thermal dissipation, electron-hole recombination, plasma diffusion, symmetry breaking at top and bottom oxide surfaces, etalon effects, etc. The fit, by way of example, may be a first degree or higher polynomial. The underlying structures may be detected based on a comparison of the feature analysis (e.g., principal component decomposition, or polynomial fit, or other) of the transient signals from a plurality of different locations. In some implementations, the slope of the polynomial fits of the transient signals from a plurality of different locations may be used to detect buried structures, such as voids. Using the raw time resolved reflectance metrology data, or processed data, such as its Fourier transform or differential reflectance, or a combination thereof, in an image of the structure, the position of the underling structure may be derived. In some implementations, a principal component analysis (PCA) process may be used with the data from the one or more images of the structure. Additionally, or alternatively, a non-PCA analysis may be used to identify a localized region in frequency space that captures the signal difference between regions on and off the underlying structure and to seek a highly correlating localized region in temporal space. The processing system 270 may alternatively or additional process the time resolved reflectance metrology data for edge detection or triangulation, e.g., using a classification library or neural network generated by the time resolved reflectance metrology device 200 (or another device) on a reference sample.

The processing system 270, which includes at least one processor 272 with memory 274, as well as a user interface including e.g., a display 276 and input devices 278. A non-transitory computer-usable storage medium 279 having computer-readable program code embodied may be used by the processing system 270 for causing the processing system 270 to control the time resolved reflectance metrology device 200 and to perform the functions including the analysis described herein. The data structures, classification library, software code, etc., for automatically implementing one or more acts described in this detailed description can be implemented by one of ordinary skill in the art in light of the present disclosure and stored, e.g., on a computer-usable storage medium 279, which may be any device or medium that can store code and/or data for use by a computer system such as the at least one processor 272. The computer-usable storage medium 279 may be, but is not limited to, flash drive, magnetic and optical storage devices such as disk drives, magnetic tape, compact discs, and DVDs (digital versatile discs or digital video discs). A communication port 277 may also be used to receive instructions that are used to program the processing system 270 to perform any one or more of the functions described herein and may represent any type of communication connection, such as to the internet or any other computer network. The communication port 277 may further export signals, e.g., measurement or inspection results and/or instructions, to another system, such as external process tools, in a feed forward or feedback process in order to adjust a process parameter associated with one or more process steps of the samples or provide rework instructions. Additionally, the functions described herein may be embodied in whole or in part within the circuitry of an application specific integrated circuit (ASIC) or a programmable logic device (PLD), and the functions may be embodied in a computer understandable descriptor language which may be used to create an ASIC or PLD that operates as herein described. The results from the analysis of the data may be stored, e.g., in memory 274 associated with the sample and/or provided to a user, e.g., via display 276, an alarm or other output device.

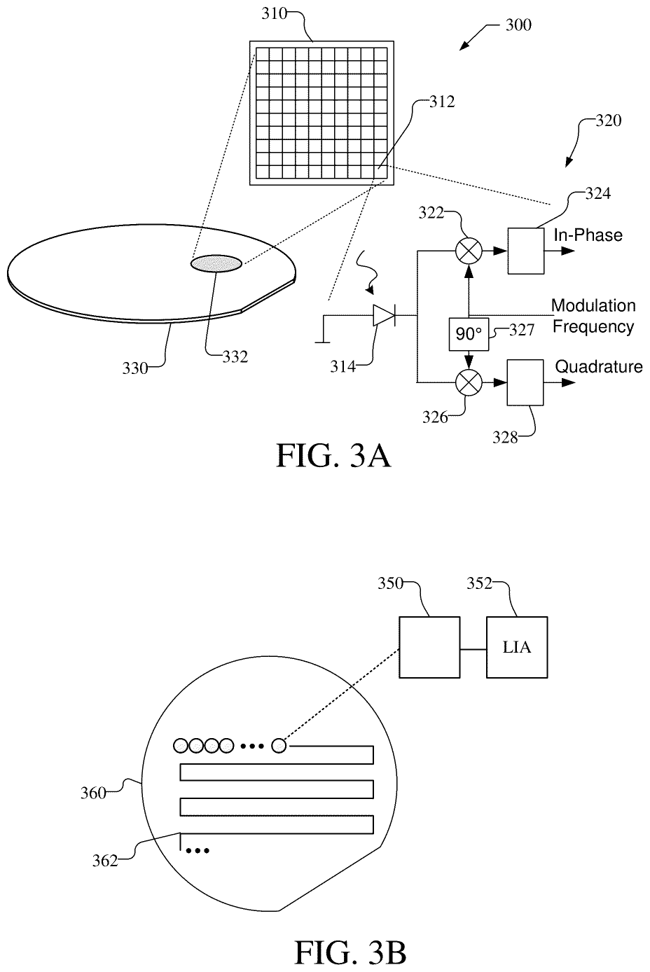

FIG. 3A illustrates a schematic representation of acquiring transient signals from a plurality of locations on a sample 330 in parallel using a lock-in camera 300. The camera 300 uses a multi-pixel array 310 that receives the reflected signal from an area 332 of the sample 330, where each pixel in the multi-pixel array 310 corresponds to a different location in the area 332. The camera 300 further uses independent phase locking for each pixel in the multi-pixel array 310. The camera 300, for example, may be used as detector 128 in FIG. 1 or detector 260 in FIG. 2, and is configured for parallel acquisition of transient signals to generate images of the sample.

FIG. 3A, for example, illustrates a close up view of a single pixel 312 in the multi-pixel array 310, which is illustrated as including a photodiode 314 and an associated phase locking circuit 320. Each pixel in the multi-pixel array 310 may be associated with an independent phase locking circuit. The phase locking circuits may be part of the camera 300 or may be separate from the camera, e.g., in a separate processor or FPGA.

As illustrated, the phase locking circuit 320 associated with the photodiode 314 (for pixel 312 in the multi-pixel array 310) may be configured to generate in-phase measurements and to generate quadrature measurements. The signal from the photodiode 314, for example, is multiplied at multiplier 322 by the modulation frequency, followed by filtering by a low pass filter 324, to generate the in-phase measurement. The modulation frequency, for example, may be provided by a local oscillator, and is the modulation frequency applied to the pump beam, probe beam or both. Additionally, the signal from the photodiode 314 may be multiplied at multiplier 326 by the modulation frequency (e.g., from a local oscillator) shifted 90° by shifter 327, followed by filtering by the low pass filter 328, to generate the quadrature measurement.

In operation, pump pulses are modulated, or both the pump pulses and the probe pulses are modulated with different frequencies, e.g., using one or more modulators (e.g., modulators 124, 124′, 226 in FIGS. 1 and 2). The camera 300 receives the reflected probe pulses with the multi-pixel array 310 which is modulated based on the modulation of the pump pulses or based on the combined modulation of the pump pulses and the probe pulses, and independently demodulates each pixel, which corresponds to a different location on the sample, to generate images of the sample, with each image being a function of a different time delay between the pump pulses and the probe pulses. For example, if both the pump pulses and the probe pulses are modulated, the received probe beam is demodulated based on the combination, e.g., sum or difference, of the modulation frequencies of the pump beam and probe beam. The camera 300 may record a change in reflectivity or surface deformation of the sample at every pixel of the images as a function of the time delay between the pump pulses and the probe pulses, with which at least one property of the sample may be characterized.

FIG. 3B illustrates a schematic representation of acquiring transient signals from a plurality of locations on a sample 360 sequentially in a scan 362 of the sample 360 using detector 350 that is a photodiode or other type of single pixel. The detector 350 may be connected to a lock-in amplifier 352, which is similar to the phase locking circuit 320 in FIG. 3A but for a single pixel, is used to demodulate the acquired transient signal. The detector 350 acquires transient signals at each location over the full range of time delays between the pump pulses and probe pulses before moving to the next location in the scan 362.

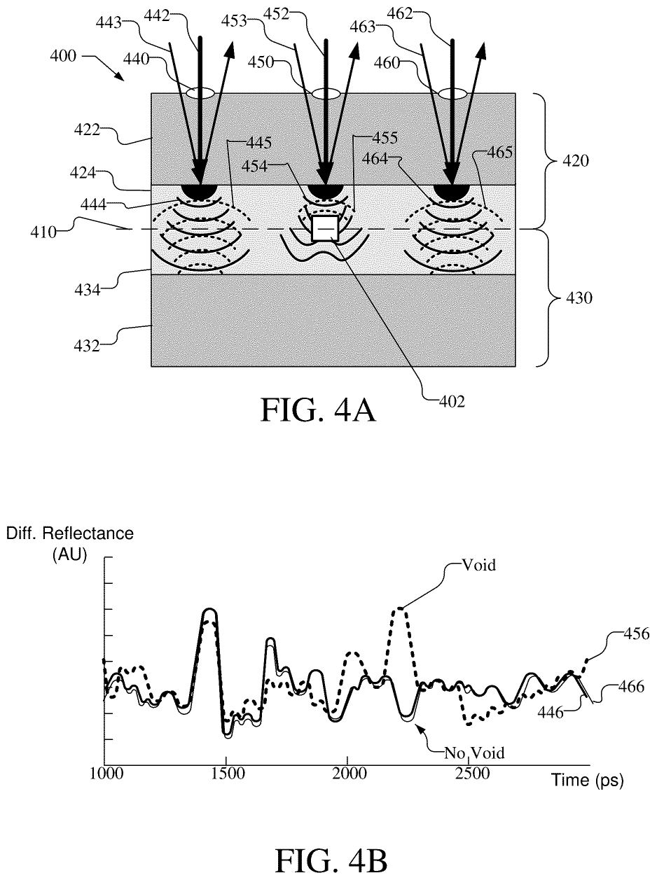

FIGS. 4A and 4B illustrate the detection of buried structures in a sample having one or more metallic layers using time resolved reflectance measurements produced in response to acoustic transient signals. FIG. 4A illustrates a sample 400 that is formed by two bonded wafers 420 and 430 with a buried structure in the form of a void 402 disposed between. Wafer 420, for example, includes a silicon substrate 422 that may have a thickness of 675 μm thick, which serves as a top layer of the sample 400, and a metallic layer 424, which may be, e.g., copper (CU), tungsten (W), or titanium (Ti), and may have a thickness of 50 nm. Wafer 430 similarly includes a metallic layer 434, which may be, e.g., CU, W, or Ti, and may have a thickness of 50 nm, on a silicon substrate 432 that may have a thickness of 675 μm thick, that serves as a bottom layer of the sample 400. The metallic layers 424 and 434 are bonded together as illustrated by line 410, with a void 402 disposed therebetween.

FIG. 4A further illustrates the measurement of acoustic transient signals at three different locations 440, 450, and 460 on the sample 400, where location 450 includes the buried void 402. Acoustic transient signals are generated due to the presence of an optically opaque material, e.g., metallic layer 434. The measurement of the acoustic transient signals may occur in parallel, e.g., using the detector with a multi-pixel array, or sequentially using a scan of the sample, as discussed above.

At locations 440, 450, and 460, illumination from the pump pulses 442, 452, and 462 are illustrated as the normally incident solid arrows. The pump pulses 442, 452, and 462, for example, may use infrared wavelengths, that penetrate the silicon substrate 422 without significant absorption, but when incident on the metallic layer 424 produce transient expansions of the metallic layer 424 at the interface with the silicon substrate 422, generating acoustic perturbations 444, 454, and 464, respectively, as illustrated by solid curved lines. The acoustic perturbations 444, 454, and 464 propagate through the metallic layer 424 over time. At locations 440 and 450, the acoustic perturbations 444 and 464 are reflected at the interface of the metallic layer 434 and the silicon substrate 432 and are returned to the surface of the metallic layer 424 as reflected acoustic perturbations 445 and 465, as illustrated by dotted curved lines. At location 450, which includes the void 402, the acoustic perturbation 454 is reflected at the interface of the metallic layer 424 and the void 402 and is returned to the surface of the metallic layer 424 as returned acoustic perturbations 455, as illustrated by dotted curved lines. The reflectance at locations 440, 450, and 460 is measured by probe beams 443, 453, and 463, which are illustrated as being incident on and reflected by the sample 400 at a non-normal angle of incidence. It should be understood, however, that the probe beams 443, 453, and 463 may be co-linear with pump pulses 442, 452, and 462, or if desired, the pump pulses 442, 452, and 462 may be incident on the sample 400 at a non-normal angle of incidence and the probe beams 443, 453, and 463 may be incident on and reflected by the sample 400 at a normal angle of incidence. The reflectance of the sample, e.g., at the interface of the metallic layer 424 and the silicon substrate 422 as measured by probe beams 443, 453, and 463 at locations 440, 450, and 460 is altered due to changes in reflectivity or surface deformation caused by the reflected acoustic perturbations 445, 455, and 465.

FIG. 4B illustrates an example graph of the acoustic transient signals 446, 456, and 466 received at locations 440, 450, and 460, respectively, in FIG. 4A. In the graph of FIG. 4B, the X axis represents the delay time between the pump and probe beams in picoseconds (ps), and the Y axis represents the differential reflectance in arbitrary units (AU). The transient signals 446, 456, 466 are in response to acoustic signals generated in the sample at locations 440, 450 and 460. It should be understood that the raw transient signals from a sample that includes a metallic layer or other strongly absorbing material may be a combination of an acoustic signal and a background signal, e.g., produced by thermal dissipation. The raw transient signals are typically processed to remove any background signal, such as thermal dissipation, which is generally a DC component, resulting in acoustic transient signals 446, 456, and 466.

As illustrated in FIG. 4B, the presence of a void or lack of a void is easily identified from the acoustic transient signals 446, 456, and 466. The presence of the void or lack of void is determined based on differences in the signal profile at a specific time delay that corresponds to when an acoustic echo is returned. As can be seen, the acoustic transient signals 446, 456, and 466 are generally similar, except where the presence of a structure, such as void 402, is present. For example, as illustrated in FIG. 4B, at approximately 2200 ps, the acoustic transient signals 446 and 466 experience a negative peak, while the acoustic transient signal 456 experiences a positive peak. Based on the difference between acoustic transient signals 446, 456, and 466 at the specific time delay corresponding to the depth at which the underlying structure is expected, e.g., 2200 ps, the presence of the void 402 at location 450 can be detected. It should be noted, however, that the differences between the acoustic transient signals 446, 456, and 466 at other time delays may be due to differences in materials or structures in the underlying layers at the different locations 440, 450, and 460, and accordingly only one specific part of the full acoustic transient signals 446, 456, and 466 (e.g., in this example, at time delay 2200 ps) is used to differentiate the signals and to identify the presence of a structure, such as void 402.

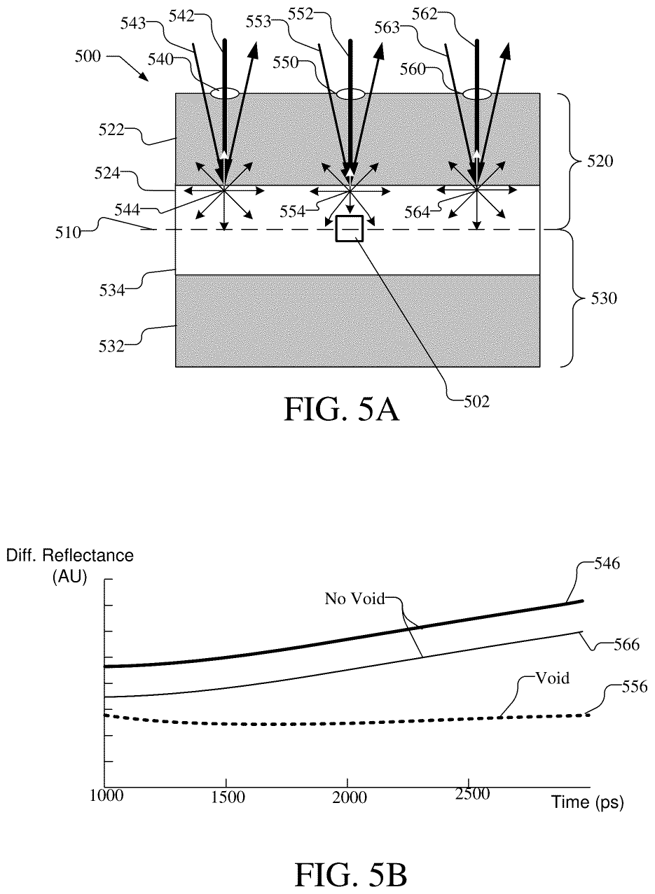

FIGS. 5A and 5B illustrate the detection of buried structures in a sample having no metallic layers (or other strongly absorbing material capable of producing acoustic signals) using time resolved reflectance measurements produced in response to non-acoustic transient signals. The reflectance measurements produced in response to the non-acoustic transient signals, for example, may be due to changes in reflectivity, although it may be possible that the non-acoustic transient signals may also or alternatively cause some changes in surface deformation, which might be detected in the reflectance measurements. FIG. 5A illustrates a sample 500 that is similar to sample 400 shown in FIG. 4A, except that sample 500 includes a silicon oxide (SiO₂) instead of a metallic layer. As illustrated, sample 500 is formed by two bonded wafers 520 and 530 with a buried structure in the form of a void 502 disposed between. Wafer 520, for example, includes a silicon substrate 522 that may have a thickness of 675 μm thick, which serves as a top layer of the sample 500, and a SiO₂ layer 524, which may have a thickness of 50 nm. Wafer 530 similarly includes a SiO₂ layer 534, which may have a thickness of 50 nm, on a silicon substrate 532 that may have a thickness of 675 μm thick, that serves as a bottom layer of the sample 500. The SiO₂ layers 524 and 534 are bonded together as illustrated by line 510, with a void 502 disposed therebetween.

FIG. 5A further illustrates the measurement of non-acoustic transient signals at three different locations 540, 550, and 560 on the sample 500, where location 550 includes the buried void 502. The sample 500 includes only optically transparent layers, i.e., there is no strongly absorbing materials that generates acoustic signals in response to the pump illumination, and accordingly, non-acoustic transient signals are produced and measured at locations 540, 550, and 560. The measurement of the non-acoustic transient signals may occur in parallel, e.g., using the detector with a multi-pixel array, or sequentially using a scan of the sample, as discussed above.

At locations 540, 550, and 560, illumination from the pump pulses 542, 552, and 562 are illustrated as the normally incident solid arrows. The pump pulses 542, 552, and 562, for example, may use infrared wavelengths that penetrate the silicon substrate 422 without significant absorption. The SiO₂ layers 524 and 534 are not strongly absorbing material and do not produce transient expansions in response to the pump pulses 542, 552, and 562, and thus no (or little) acoustic signals are generated in the SiO₂ layers 524 and 534. The pump pulses 542, 552, and 562, however, produce non-acoustic transient perturbations, e.g., due to the absorption of pump beams via multi-photon ionization or due to distortion of the sample material properties at the interface. Thus, non-acoustic transient perturbations 544, 554, and 564 are produced at locations 540, 550, and 560, respectively, as illustrated by outwardly radiating arrows. The non-acoustic transient perturbations 544, 554, and 564 are produced in response to the pump pulses 542, 552, and 562, respectively, and are generated by non-acoustic physical phenomena, such as one or more of thermal dissipation, electron-hole recombination, plasma diffusion, symmetry breaking at top and bottom oxide surfaces, etalon effects within the void 502, etc. Unlike the acoustic transient perturbations illustrated in FIG. 4A, the non-acoustic transient perturbations 544, 554, and 564 are not reflected and returned by structures, but instead decay over time. The presence of structures, such as void 502, affect the rate of decay of the non-acoustic transient perturbations 544, 554, and 564.

The reflectance at locations 540, 550, and 560 is measured by probe beams 543, 553, and 563, which are illustrated as being incident on and reflected by the sample 500 at a non-normal angle of incidence. It should be understood, however, that the probe beams 543, 553, and 563 may be co-linear with pump pulses 542, 552, and 562, or if desired, the pump pulses 542, 552, and 562 may be incident on the sample 500 at a non-normal angle of incidence and the probe beams 543, 553, and 563 may be incident on and reflected by the sample 500 at a normal angle of incidence. The reflectance of the sample, e.g., at the interface of the SiO₂ layers 524 and the silicon substrate 522 as measured by probe beams 543, 553, and 563 at locations 540, 550, and 560 is altered due to changes in reflectivity of the SiO₂ layers 524 caused by the non-acoustic transient perturbations 544, 554, and 564. In some situations, the reflectance of the sample may also or alternatively be due to changes in surface deformation. The non-acoustic transient perturbations 544, 554, and 564 decay over time and, accordingly, the measured reflectance produced in response to the non-acoustic transient perturbations 544, 554, and 564 will likewise change over time. In general, for measurements of acoustic transient signals, as illustrated in FIGS. 4A and 4B, non-acoustic transient perturbations 544, 554, and 564 would be considered background signals and are removed from the raw transient signal measurements. In the present implementation, however, there is no or little acoustic information, and accordingly, the raw transient signals measured and analyzed for locations 540, 550, and 560 is the non-acoustic transient perturbations 544, 554, and 564.

FIG. 5B illustrates an example graph of the non-acoustic transient signals 546, 556, and 566 received at locations 540, 550, and 560, respectively, in FIG. 5A. The graph of FIG. 5B is similar to the graph of FIG. 4B, where the X axis represents the delay time between the pump and probe beams in picoseconds (ps), and the Y axis represents the differential reflectance in arbitrary units (AU). The measured non-acoustic transient signals 546, 556, 566 are in response to non-acoustic perturbations 544, 554, 564 produced at locations 540, 550 and 560 in the sample 500. The presence of the void 502 at location 550, however, results in a difference in the non-acoustic perturbation 554 with respect to the non-acoustic perturbations 544 and 564 at locations 540 and 560, and accordingly, the resulting measured non-acoustic transient signals produced in response to these perturbations will likewise differ. As illustrated in FIG. 5B, the non-acoustic transient signals 546 and 566 from locations 540 and 560, where no void is present, are generally similar in attributes or traits such as the shape or slope of the transient signals. In contrast, the non-acoustic transient signals 556 from locations 550, where the void 502 is present, is dissimilar to attributes or traits, such as the shape or slope to the non-acoustic transient signals 546 and 566 at other locations 540 and 560 on the sample 500. Accordingly, analysis of the transient signals may be performed to differentiate between various attributes or traits of the transient signals from different locations. The attributes or trains of the transient signals from different locations may be used to determine whether the measurements are carried out at locations with voids or locations without voids. As an example, the analysis may be based on polynomial or other curve fits, such as exponential, of the transient signals at the different locations or other types of analysis, such as principal component analysis (PCA), or a comparison of the attributes or traits, such as the shape, slope, rate of change, etc.

While the presence of the void or lack of void was determined based on a difference in the transient signals at a specific time delay, e.g., a single point on the time delay axis, if the transient signals are produced by acoustic perturbations, as discussed in FIG. 4B, if the transient signals are produced by non-acoustic perturbations, such as one or more of thermal dissipation, electron-hole recombination, plasma diffusion, symmetry breaking at top and bottom oxide surfaces, etalon effects, etc., the presence of the void or lack of void may be determined based on the difference in the transients signals over a range of time delays, e.g., a plurality of points on the time delay axis. For example, the number of time delays used to analyze the transient signals may be dependent on the sample under test, but should be adequate to identify one or more features of the non-acoustic transient signals, such as the shape, slope, rate of change, etc., that characterizes desired attributes or traits, such as the rate of decay of the non-acoustic transient perturbations, from which the presence of a buried structure, such as a void, may be determined.

Accordingly, despite the lack of any significant acoustic signal in the sample 500, the presence of the void 502 may be detected based on, e.g., the characteristic or trait of the non-acoustic transient signal over time, which may be determined using a polynomial or other curve fit, such as exponential, or other type of analysis, e.g., PCA, of the non-acoustic transient signals from multiple locations on the sample. For example, by comparing the non-acoustic transient signals provided over time, including but not limited to the slope or rate of change of the non-acoustic transient signals from the multiple locations, the void 502 may be detected. Moreover, an image of the sample 500, including the presence of the void 502, may be generated based on the relative non-acoustic transient signals from the multiple locations.

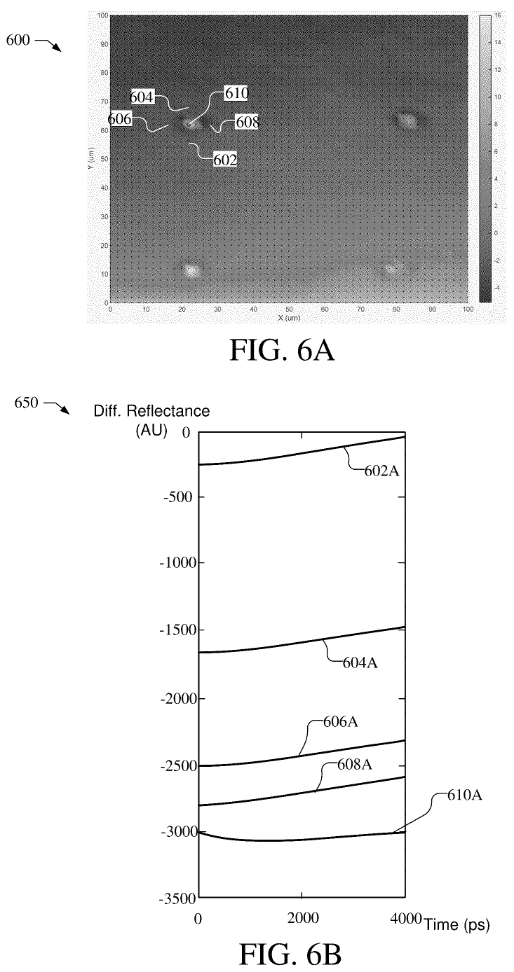

FIGS. 6A and 6B illustrate the imaging and detection of buried structures, such as voids, in a sample having no metallic layers (other strongly absorbing material that produces acoustic signals) using time resolved reflectance measurements produced by non-acoustic transient signals.

FIG. 6A illustrates a two-dimensional image 600 of an area of a sample that includes a plurality of buried structures, e.g., voids. The X axis and Y axis of the image 600 represent the X and Y dimensions on the sample. The image 600 is formed by measuring non-acoustic transient signals over a plurality of locations over an area of 100 μm×100 μm, using 2 μm steps with a spot size of approximately 3-5 μm. Based on the polynomial fit of the non-acoustic transient signals from the plurality of locations, 1 μm voids may be detected.

FIG. 6B illustrates a graph 650 of the non-acoustic transient signals taken from five locations 602, 604, 606, 608, and 610 in the image 600 shown in FIG. 6A. Location 610 corresponds to the location of a void. The X axis of graph 650 represents the delay time between the pump and probe beams in picoseconds (ps), and the Y axis represents the differential reflectance in arbitrary units (AU). Graph 650 illustrates curves representing the polynomial fit of non-acoustic transient signals 602A, 604A, 606A, 608A, and 610A taken from the five locations 602, 604, 606, 608, and 610, respectively, in the image 600. As can be seen, the polynomial fit of non-acoustic transient signals 602A, 604A, 606A, and 608A are similar, but the polynomial fit of the non-acoustic transient signal 610A corresponding to a void is significantly different, e.g., in shape, slope, and rate of change. Thus, a comparison of the polynomial fits, including but not limited to the slope or rate of change of the polynomial fits, of the non-acoustic transient signals from the multiple locations, identifies the presence of the void.

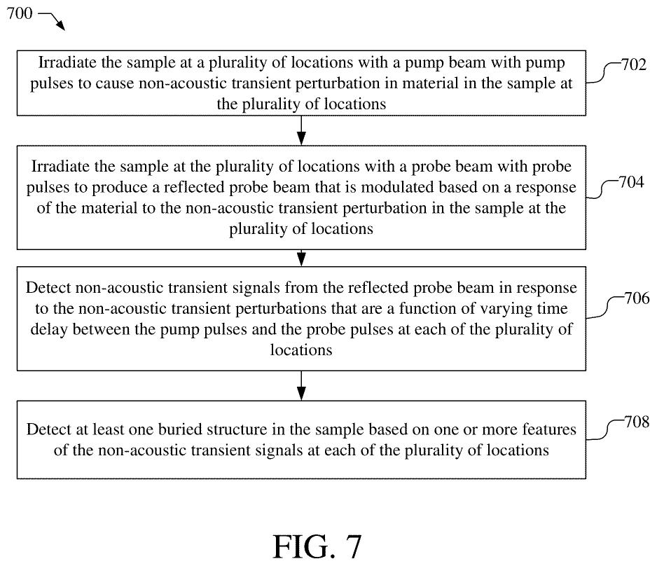

FIG. 7 is a flow chart 700 illustrating a process of non-destructive detection of buried structures in a sample using non-acoustic transient signals, as discussed herein. The process, for example, may be performed using time resolved reflectance metrology devices 100 or 200 shown in FIG. 1 or 2, respectively.

As illustrated, at block 702, the process includes irradiating the sample at a plurality of locations with a pump beam with pump pulses to cause non-acoustic transient perturbation in material in the sample at the plurality of locations, e.g., as illustrated in FIGS. 5A and 5B. The non-acoustic transient perturbations may not include acoustic signals, e.g., as illustrated in FIGS. 5A and 5B. The non-acoustic transient perturbations, for example, may be produced by one or more of thermal dissipation, electron-hole recombination (probably generated in Si), plasma diffusion, symmetry breaking at top and bottom oxide surfaces, and any etalon effects.

At block 704, the sample is irradiated at the plurality of locations with a probe beam with probe pulses to produce a reflected probe beam that is modulated based on a response of the material to the non-acoustic transient perturbation in the sample at the plurality of locations, e.g., as illustrated in FIGS. 5A and 5B. By way of example, the sample may be scanned to irradiate the sample at the plurality of locations, e.g., by an actuator that is configured to produce relative motion between the sample and the metrology device, wherein the pump arm and the probe arm irradiate the sample at the plurality of locations using the relative motion to scan the sample as illustrated in FIG. 3B. In another example, a lock-in camera with a multi-pixel array may be used to acquire the non-acoustic transient signals from the reflected probe beam at each of the plurality of locations in parallel, e.g., as illustrated in FIG. 3A.

At block 706, non-acoustic transient signals are detected from the reflected probe beam in response to the non-acoustic transient perturbations that are a function of varying time delay between the pump pulses and the probe pulses at each of the plurality of locations, e.g., as illustrated in FIGS. 5A and 5B.

At block 708, at least one buried structure in the sample is detected based on one or more features of the non-acoustic transient signals at each of the plurality of locations, e.g., as illustrated in FIGS. 5A and 5B. In some implementations, an image of the at least one buried structure in the sample may be generated based on the one or more features of the non-acoustic transient signals at each of the plurality of locations. The one or more features of the non-acoustic transient signals, for example, may include one or more features produced over a plurality of time delays between the pump pulses and the probe pulses. The at least one buried structure may be detected by comparing the non-acoustic transient signals at the plurality of locations, e.g., as illustrated in FIGS. 5A and 5B and FIGS. 6A and 6B. The at least one buried structure, for example, may be a void in a material that is transparent to wavelengths of light used to irradiate the sample, e.g., as illustrated in FIGS. 5A and 5B. For example, the material may be SiO₂ and the wavelengths of light may be infrared.

In some implementations, time resolved reflectance metrology devices, such as time resolved reflectance metrology device 100 shown in FIG. 1 or time resolved reflectance metrology device 200 shown in FIG. 2, may be used to acoustically detect or image buried structure and voids. As discussed above, as voids or inclusions may be intentionally or inadvertently formed between bonded layers, such as interfacial voids generated during hybrid bonding process, e.g., chip to chip, chip to wafer, and wafer to wafer.

In some instances, samples with bonded layers, such as bonded wafers, may have a relatively thick layer (e.g., 775 μm) on both sides of the sample, and standard photoacoustic techniques that generates acoustics at the top surface may not be able to locate buried structures/voids underneath the thick top layer. This is due to limitations, for example, imposed by the laser repetition rate on the delay between the pump pulses and the probe pulses.

To circumvent such limitations, the wavelengths of light used by the metrology device may be selected such that the top layer is transparent to the light. For example, typically, the top layer is silicon (Si), and accordingly, infrared (IR) wavelengths may be used to generate and detect the acoustic signal at the interface between the top silicon layer and the underlying metal layer because silicon is transparent to infrared or near infrared (NIR) wavelengths.

In some cases, however, some light may be reflected from the top surface of the top layer, which increases the noise on the detector, thereby obscuring the signal from the interface between the top layer and the underlying layer. For example, the top surface of a top silicon layer may include one or more dielectric layers that reflect the infrared light. In some cases, as much as 70% of the light reaching the detector is contributed from the top surface reflection, obscuring the weaker signal from the interface between the top layer and underlying layer.

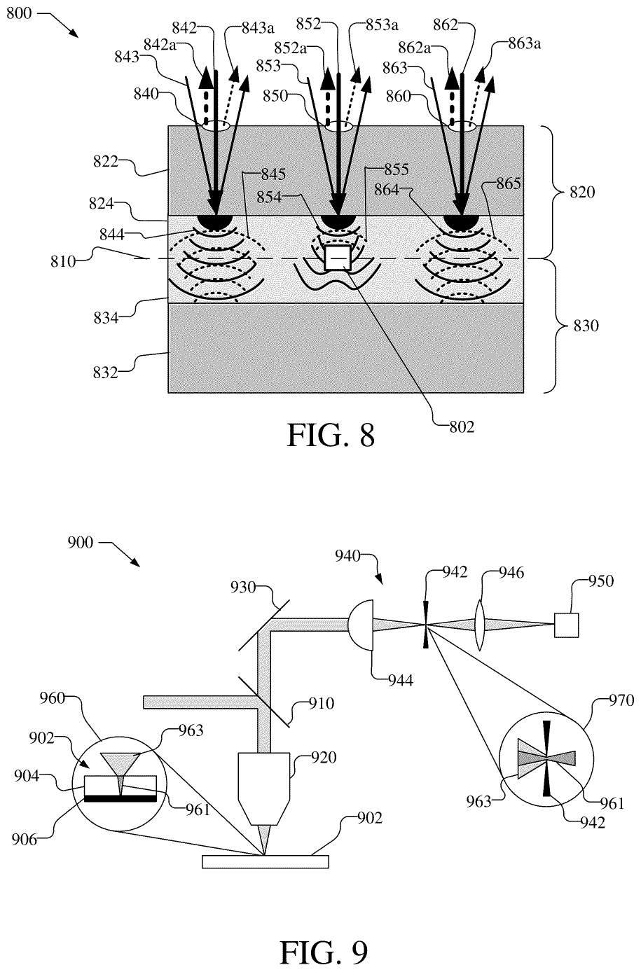

FIG. 8, by way of example, illustrates a sample 800 that is formed by two bonded wafers 820 and 830 with a buried structure 802 disposed between. Wafer 820, for example, includes a relatively thick top layer 822, which may be a silicon substrate, with a thickness of 775 μm, which serves as a top layer of the sample 800, and an underlying layer 824. The underling layer 824 may be opaque, such as a metallic layer, which may be, e.g., copper (CU), tungsten (W), or titanium (Ti), and may have a thickness of 50 nm. In some implementations the underlying layer 824 may not be opaque to all wavelengths of light, e.g., such as SiO₂, as discussed with reference to layer 524 in FIG. 5A. Wafer 830 similarly includes a layer 834, which may be an opaque or at least partially transparent layer, such as a metallic layer, e.g., CU, W, or Ti, or a SiO₂ layer, and may have a thickness of 50 nm. Wafer 830 further includes a relatively thick layer 832, which may be a silicon substrate 832 with a thickness of 775 μm, that serves as a bottom layer of the sample 800. The metallic layers 824 and 834 are bonded together as illustrated by line 810, with the buried structure 802 disposed therebetween.

FIG. 8 further illustrates the measurement of acoustic transient signals at three different locations 840, 850, and 860 on the sample 800, where location 850 includes a buried structure 802. FIG. 8 is similar to FIG. 4A, but illustrates the pump pulses and probe pulses being reflected from the top surface of the top layer 822, which is partially transparent to the wavelengths of light in the pump and probe pulses, in addition to being reflected from the interface between the top layer 822 and the underlying layer 824, which is opaque or at least partially transparent to the wavelengths of light in the pump and probe pulses. Acoustic transient signals may be generated due to the presence of an optically opaque material, e.g., at the interface of the top layer 822 and the underlying layer 824. The measurement of the acoustic transient signals may occur in parallel, e.g., using the detector with a multi-pixel array, or sequentially using a scan of the sample, as discussed above.

At locations 840, 850, and 860, illumination from the pump pulses 842, 852, and 862 are illustrated as the normally incident solid arrows. The pump pulses 842, 852, and 862, for example, may use infrared wavelengths, that should penetrate the top layer 822 without significant absorption. However, in some instances, such as when the top layer 822 includes dielectric layers at the top surface, a portion of the pump pulses 842a, 852a, and 862a is reflected by the top surface of the top layer 822, as illustrated with dotted arrows. When the pump pulses 842, 852, and 862 are incident on an opaque underlying layer 824, they produce transient expansions of the opaque underlying layer 824 at the interface with the top layer 822, generating acoustic perturbations 844, 854, and 864, respectively, as illustrated by solid curved lines. The acoustic perturbations 844, 854, and 864 propagate through the underlying layer 824 over time. At locations 840 and 850, the acoustic perturbations 844 and 864 are reflected at the interface of the layer 834 and the silicon substrate 832 and are returned to the surface of the underlying layer 824 as reflected acoustic perturbations 845 and 865, as illustrated by dotted curved lines. At location 850, which includes an underlying structure 802, such as a void or a solid material, the acoustic perturbation 854 is reflected at the interface of the underlying layer 824 and the structure 802 and is returned to the surface of the underlying layer 824 as returned acoustic perturbations 855, as illustrated by dotted curved lines.

The reflectance at locations 840, 850, and 860 is measured by probe beams 843, 853, and 863, which are illustrated as being incident on and reflected by the sample 800. The probe beams 843, 853, and 863, for example, may use infrared wavelengths, that should penetrate the top layer 822 without significant absorption. However, in some instances, such as when the top layer 822 includes dielectric or other types of layers at the top surface or even when no layers are present on the top surface, a portion of the probe beams 843a, 853a, and 863a is reflected by the top surface of the top layer 822, as illustrated with dotted arrows. The probe beams 843, 853, and 863 are illustrated in FIG. 8 at a non-normal angle of incidence. It should be understood, however, that the probe beams 843, 853, and 863 may be co-linear with pump pulses 842, 852, and 862, or if desired, the pump pulses 842, 852, and 862 may be incident on the sample 800 at a non-normal angle of incidence and the probe beams 843, 853, and 863 may be incident on and reflected by the sample 800 at a normal angle of incidence. The reflectance of the sample, e.g., at the interface of the underlying layer 824 and the top layer 822 as measured by probe beams 843, 853, and 863 at locations 840, 850, and 860, is altered due to changes in reflectivity or surface deformation caused by the reflected acoustic perturbations 845, 855, and 865.

In order to prevent obscuring the transient signals produced at the interface of the top layer 822 and the opaque layer 824 by the background signal, i.e., obscuring signals from acoustic perturbations 844, 854, and 864 by the reflection of the probe beams 843a, 853a, and 863a by the top surface of the top layer 822, a confocal lens arrangement before the detector may be used. While FIG. 8 illustrates transient signals as acoustic perturbations 844, 854, and 864 produced in an opaque underlying layer, transient signals from non-acoustic perturbations in an at least partially transparent underlying layer, such as non-acoustic transient perturbations 544, 554, and 564 illustrated in FIG. 5A, may likewise be obscured by the background signal. The confocal lens arrangement optically isolates the transient signal from the background signal and enables improved detection of the acoustic perturbations, as illustrated in FIG. 4A and FIG. 8, or non-acoustic perturbations, as illustrated in FIG. 5A, to detect at least one buried structure, e.g., a structure in or under the underlying layer, such as device structures, voids or inclusions.

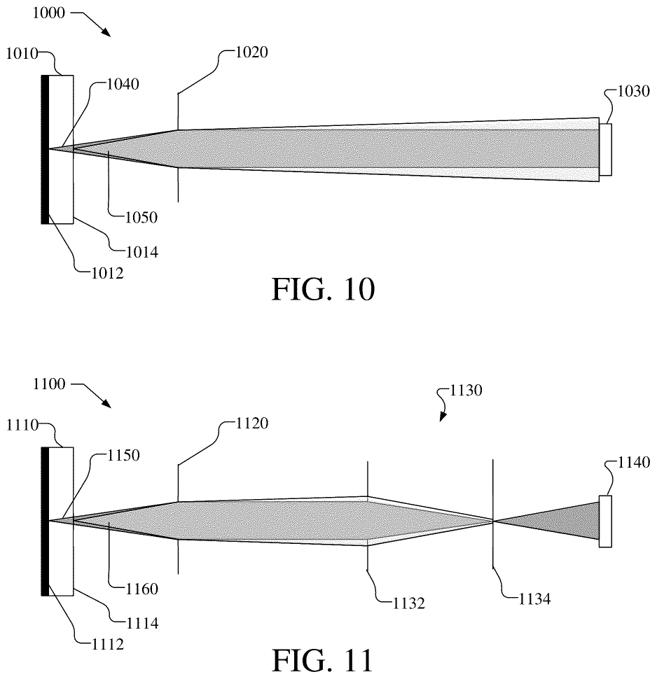

FIG. 9, by way of example, illustrates an example portion of a time resolved reflectance metrology device 900, such as time resolved reflectance metrology device 100 shown in FIG. 1 or time resolved reflectance metrology device 200 shown in FIG. 2. The portion of a time resolved reflectance metrology device 900 includes a beam splitter 910, an objective lens 920, a folding mirror 930, and a confocal lens arrangement 940, including a pinhole 942, before the detector 950. As illustrated, the incident probe beam is directed by beam splitter 910 towards the objective lens 920, which focuses the light on the sample 902 at normal incidence. The reflected probe beam is received by the objective lens 920 is directed by the beam splitter 910 towards the confocal lens arrangement 940, via the folding mirror 930. The reflected probe beam is collimated and refocused by the confocal lens arrangement 940, illustrated by lenses 944 and 946. The pinhole 942 is located in the image plane, and blocks all the reflected light except the light from the focal plane. As illustrated by inset 960, which shows the sample 902 with an interface between a top layer 904 and underlying opaque layer 906, the interface is in a different focal plane than the top surface of the top layer 904. The pinhole 942 is positioned so that the beam 961 that is focused on the interface of the top layer 904 and underlying opaque layer 906 is imaged at the pinhole 942, and light 963 in the remaining beam 963 is blocked by the pinhole 942. Consequently, most of the reflected beam 963 from the top surface of the top layer 904 of the sample 902 will be blocked by the pinhole 942 and, as illustrated by inset 970, the beam 961 focused at the interface of the top layer 904 and underlying layer 906 passes through the pinhole 942 and is received by the detector 950, enabling improved detection of acoustic or non-acoustic perturbations, as illustrated in FIGS. 4A, 5A, and FIG. 8, to detect a structure, such as a device structure, void or inclusion, in a layer, e.g., in or under opaque layer 906, that underlies the top layer 904 of the sample 902.

In some implementations, the objective lens 920 may focus the light onto a line on the sample 902 as opposed to a spot. The confocal lens arrangement 940 may use a slit instead of pinhole 942, and the reflected light may be focused by lenses 944 onto the slit, which passes light reflected from the focal plane but blocks the reflected light from the top layer 904. The detector 950 may be linear array of pixels that receives the light that passes the slit via lens 946. Cylindrical lenses, for example, may be used in objective lens 920 and lenses 944 and 946 to focus the light in lines. The line that is focused on the sample 902 simultaneously irradiates the sample 902 at a plurality of locations that may be scanned over the sample 902 to increase throughput.

FIG. 10, by way of example, illustrates a simplified view of the optical path 1000, including the sample 1010, an objective lens 1020, and the detector 1030, without the use of a confocal lens arrangement. As illustrated, the light 1040 focused by the objective lens 1020 at the interface 1012 between the top layer and underlying layer of the sample 1010 is reflected and received by the detector 1030. However, a large portion of light 1050 focused by the objective lens 1020 at the top surface 1014 of the sample 1010 may also be reflected and received by the detector 1030.

FIG. 11, in contrast, illustrates a simplified view of the optical path 1100 that includes the sample 1110, an objective lens 1120, a confocal lens arrangement 1130 including a lens 1132 and pinhole 1134, and a detector 1140. As illustrated, the light 1150 focused by the objective lens 1120 at the interface 1112 between the top layer and underlying layer of the sample 1110 is reflected and refocused by the lens 1132 to the pinhole 1134, which may be positioned at the image plane, so that the light passes through the pinhole 1134 and is received by the detector 1140. The light 1160 focused by the objective lens 1120 at the top surface 1114 of the sample 1110, which is at a different focal plane the interface 1112, may be reflected, but will be substantially blocked by the pinhole 1134, so that it is not received by the detector 1140. Accordingly, the background reflection from the top surface 1114 of the sample 1110 is substantially eliminated.

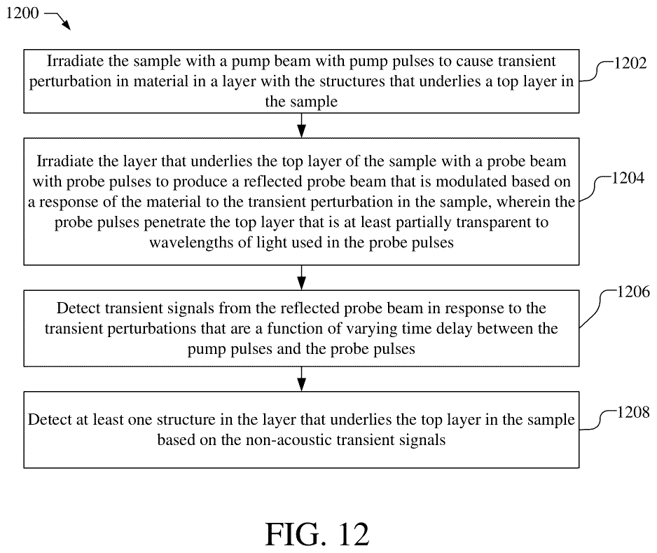

FIG. 12 is a flow chart 1200 illustrating a process of non-destructive detection of structures in a sample using transient signals, as discussed herein. The process, for example, may be performed using time resolved reflectance metrology devices 100 or 200 shown in FIG. 1 or 2, respectively.

As illustrated, at block 1202, the process includes irradiating the sample with a pump beam with pump pulses to cause transient perturbations in material in a layer with the structures that underlies a top layer in the sample, e.g., as illustrated in FIGS. 4A, 4B, 5A, 5B, and 8. The transient perturbations may not include acoustic signals, e.g., as illustrated in FIGS. 5A and 5B.

At block 1204, the layer that underlies the top layer of the sample is irradiated with a probe beam with probe pulses to produce a reflected probe beam that is modulated based on a response of the material to the transient perturbations in the sample, wherein the probe pulses penetrate the top layer that is at least partially transparent to wavelengths of light used in the probe pulses, e.g., as illustrated in FIGS. 4A, 4B, 5A, 5B, and 8. By way of example, the sample may be scanned to irradiate the sample at a plurality of locations, e.g., by an actuator that is configured to produce relative motion between the sample and the metrology device, wherein the pump arm and the probe arm irradiate the sample at the plurality of locations using the relative motion to scan the sample as illustrated in FIG. 3B. In some implementations, the probe beam may be focused in a line on the sample to simultaneously irradiate the sample at the plurality of locations and the relative motion scans the line over the sample. In another example, a lock-in camera with a multi-pixel array may be used to acquire the transient signals from the reflected probe beam at each of a plurality of locations in parallel, e.g., as illustrated in FIG. 3A.

At block 1206, transient signals are detected from the reflected probe beam in response to the transient perturbations that are a function of varying time delay between the pump pulses and the probe pulses, e.g., as illustrated in FIGS. 4A, 4B, 5A, 5B, and 8.

At block 1208, at least one structure in the layer that underlies the top layer in the sample is detected based on the transient signals, e.g., as illustrated in FIGS. 4A, 4B, 5A, 5B, and 8. In some implementations, an image of the at least one structure in the sample may be generated based on the transient signals. One or more features of the transient signals may be used to detect the at least one structure and the one or more features, for example, may include one or more features produced over a plurality of time delays between the pump pulses and the probe pulses. The at least one structure may be detected by comparing the transient signals at a plurality of locations, e.g., as illustrated in FIGS. 5A and 5B and FIGS. 6A and 6B. The at least one buried structure, for example, may be a void in a material that is transparent to wavelengths of light used to irradiate the sample, e.g., as illustrated in FIGS. 5A and 5B. The top layer may be a silicon substrate and the wavelengths of light used in the probe pulse may be infrared, and the layer with the structures that underlies the top layer is opaque to the wavelengths of light used in the probe pulses.

In some implementations, the probe pulses reflect from a top surface of the top layer and from an interface between the layer and the top layer, and the method may further include preventing reflections from the top surface of the top layer from being detected using a confocal lens arrangement, e.g., as illustrated in FIGS. 8, 9, and 11. A means for preventing reflections from the top surface of the top layer from being detected by the detector, for example, may include a confocal lens arrangement, such as discussed in relation to FIGS. 8, 9, and 11. For example, a confocal lens arrangement may include a pinhole or a slit that is positioned in an image plane for an interface between the top layer and the layer with the structures, e.g., as discussed in relation to FIGS. 9 and 11.

In some implementations, the transient perturbations may be acoustic transient perturbations and acoustic transient signals may be detected from the reflected probe beam in response to the acoustic transient perturbations, e.g., as illustrated in FIGS. 4A and 8. In some implementations, the transient perturbations may be non-acoustic transient perturbations and non-acoustic transient signals may be detected from the reflected probe beam in response to the non-acoustic transient perturbations, e.g., as illustrated in FIGS. 5A and 5B. The non-acoustic transient perturbations, for example, may be produced by one or more of thermal dissipation, electron-hole recombination (probably generated in Si), plasma diffusion, symmetry breaking at top and bottom oxide surfaces, and any etalon effects.

The above description is intended to be illustrative, and not restrictive. For example, the above-described examples (or one or more aspects thereof) may be used in combination with each other. Other implementations can be used, such as by one of ordinary skill in the art upon reviewing the above description. Also, in the above Description, various features may be grouped together to streamline the disclosure. The inventive subject matter may lie in less than all features of a particular disclosed implementation. Thus, the following aspects are hereby incorporated into the Description as examples or implementations, with each aspect standing on its own as a separate implementation, and it is contemplated that such implementations can be combined with each other in various combinations or permutations. Therefore, the spirit and scope of the appended claims should not be limited to the foregoing description.

What is claimed is:

1. A metrology device for non-destructive detection of structures in a sample, comprising:
a pump arm that irradiates the sample with pump pulses to cause transient perturbations in material in a layer with the structures that underlies a top layer in the sample;
a probe arm that irradiates the layer that underlies the top layer of the sample with probe pulses to produce a reflected probe beam that is modulated based on a response of the material to the transient perturbations, wherein the probe pulses penetrate the top layer that is at least partially transparent to wavelengths of light used by the probe arm;
a detector that acquires transient signals from the reflected probe beam in response to the transient perturbations that are a function of varying time delay between the pump pulses and the probe pulses; and
at least one processor coupled to the detector and is configured to detect at least one structure in the layer that underlies the top layer in the sample based on the transient signals.

2. The metrology device of claim 1, wherein the probe pulses reflect from a top surface of the top layer and from an interface between the layer and the top layer, the metrology device further comprising:
a confocal lens arrangement before the detector that prevents reflections from the top surface of the top layer from being received by the detector.

3. The metrology device of claim 2, wherein the confocal lens arrangement comprises a pinhole or slit positioned in an image plane for an interface between the top layer and the layer with the structures.

4. The metrology device of claim 1, wherein the at least one processor is further configured to generate an image of the at least one structure in the sample based on the transient signals.

5. The metrology device of claim 1, further comprising an actuator configured to produce relative motion between the sample and the metrology device, wherein the pump arm and the probe arm irradiate the sample at a plurality of locations using the relative motion to scan the sample.

6. The metrology device of claim 1, wherein the detector is a lock-in camera with a multi-pixel array that acquires the transient signals from the reflected probe beam at each of a plurality of locations in parallel.

7. The metrology device of claim 1, wherein the top layer is a silicon substrate and the wavelengths of light used by the probe arm are infrared, and the layer with the structures that underlies the top layer is opaque to the wavelengths of light used by the probe arm.

8. The metrology device of claim 1, wherein the at least one structure is detected based on a comparison of the transient signals at a plurality of locations.

9. The metrology device of claim 1, wherein the transient perturbations are non-acoustic transient perturbations and the detector acquires non-acoustic transient signals from the reflected probe beam in response to the non-acoustic transient perturbations.

10. The metrology device of claim 9, wherein the non-acoustic transient perturbations are produced by one or more of thermal dissipation, electron-hole recombination, plasma diffusion, symmetry breaking at top and bottom oxide surfaces, and etalon effects.

11. A method for non-destructive detection of structures in a sample, comprising:
irradiating the sample with a pump beam with pump pulses to cause transient perturbations in material in a layer with the structures that underlies a top layer in the sample;
irradiating the layer that underlies the top layer of the sample with a probe beam with probe pulses to produce a reflected probe beam that is modulated based on a response of the material to the transient perturbations in the sample, wherein the probe pulses penetrate the top layer that is at least partially transparent to wavelengths of light used in the probe pulses;
detecting transient signals from the reflected probe beam in response to the transient perturbations that are a function of varying time delay between the pump pulses and the probe pulses; and
detecting at least one structure in the layer that underlies the top layer in the sample based on the transient signals.

12. The method of claim 11, wherein the probe pulses reflect from a top surface of the top layer and from an interface between the layer and the top layer, the method further comprising:
preventing reflections from the top surface of the top layer from being detected using a confocal lens arrangement.

13. The method of claim 12, wherein the confocal lens arrangement comprises a pinhole or slit positioned in an image plane for an interface between the top layer and the layer with the structures.

14. The method of claim 11, further comprising generating an image of the at least one structure in the sample based on the transient signals.

15. The method of claim 11, further comprising scanning the sample to irradiate the sample at a plurality of locations.

16. The method of claim 11, further comprising using a lock-in camera with a multi-pixel array to acquire the transient signals from the reflected probe beam at each of a plurality of locations in parallel.

17. The method of claim 11, wherein the top layer is a silicon substrate and the wavelengths of light used in the probe pulses are infrared, and the layer with the structures that underlies the top layer is opaque to the wavelengths of light used in the probe pulses.

18. The method of claim 11, wherein detecting the at least one structure comprises comparing the transient signals at a plurality of locations.

19. The method of claim 11, wherein the transient perturbations are non-acoustic transient perturbations and non-acoustic transient signals are detected from the reflected probe beam in response to the non-acoustic transient perturbations.

20. The method of claim 19, wherein the non-acoustic transient perturbations are produced by one or more of thermal dissipation, electron-hole recombination, plasma diffusion, symmetry breaking at top and bottom oxide surfaces, and etalon effects.

21. A metrology device for non-destructive detection of structures in a sample, comprising:
a pump arm that irradiates the sample with pump pulses to cause transient perturbations in material in a layer with the structures that underlies a top layer in the sample;
a probe arm that irradiates the layer that underlies the top layer of the sample with probe pulses to produce a reflected probe beam that is modulated based on a response of the material to the transient perturbations, wherein the probe pulses penetrate the top layer that is at least partially transparent to wavelengths of light used by the probe arm and the probe pulses reflect from a top surface of the top layer and from an interface between the layer and the top layer;
a detector that acquires transient signals from the reflected probe beam in response to the transient perturbations that are a function of varying time delay between the pump pulses and the probe pulses;
a means for preventing reflections from the top surface of the top layer from being detected by the detector; and
at least one processor coupled to the detector and is configured to detect at least one structure in the layer that underlies the top layer in the sample based on the transient signals.
